(19) United States
(12) Patent Application Publication
(10) Pub. No.: US 2004/0209401 A1
(43) Pub. Date: Oct. 21, 2004

(54) Arrangement structure applying to sawing a package panel

(76) Inventor: Tsung-Hung Lee, Chung-Li (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/414,086

(22) Filed: Apr. 16, 2003

(51) Int. Cl. H01L 21/44; H01L 21/301; H01L 23/02

(52) U.S. Cl. 438/113; 438/460

(57) ABSTRACT

The present invention is to provide an arrangement structure applying to sawing a package panel. The present invention applies for two sizes of the rectangle panel. When the length of the panel is 16 inch and the width of the panel is 13.3 inch; there are eight pieces rectangle integrated circuit (IC) substrates arranged on the rectangle panel, and wherein a short side of each of those IC substrates is about 67 mm to 78 mm and a long side of each of those IC substrates is about 172 mm to 192 mm. Besides, as the length of the panel is 20 inch and the width of the panel is 16 inch, there are twelve or fourteen pieces rectangle integrated circuit (IC) substrates arranged on the panel. Hence, the present invention can obtain an effective balance between the substrate size and the manufacturing ability of the machine and simultaneously give consideration to the utility rate of the panel arrangement and the yield of manufacturing so as the present invention can effectively improve the yield and cost down the cost.

### BACKGROUND OF THE INVENTION

1. Field of the Invention

The present invention generally relates to an arrangement structure applying to sawing a package panel, and more particularly relates to arrangement structure applying for obtaining most chip dies as sawing a package panel.

2. Description of the Prior Art

With development trend of high frequency, high I/O leads, and micro-miniaturization of the information and communication products, the requirement of the package technology, such as the ball grid array and the chip size/scale package (CSP), is substantially grown.

The prior arrangement structure of the package panel, as shown in the FIG. 1, is including a panel 10 having a fixed size, wherein the panel provides with two sizes of the 16 inch×20 inch and the 13.3 inch×16 inch. Herein is choosing the size of the 16 inch×20 inch of the panel for example. There are twelve rectangle IC substrates 14 arranged in the effective using area 12 of the panel 10 so as to bond a plurality of chip dies 16 on each IC substrate 14. Owing to the size of the prior panel 10 is fixed, if it wants to have the maximum area utility rate of the panel 10, it must take consideration on the size of the IC substrate 14, the arrangement of IC substrate 14 on the panel 10, and the arrangement of the chip dies 16 on each IC substrate 14 so as to obtain the maximum chip dies after sawing the package by using the same size of the panel and the IC substrate.

Wherein, on the size of the IC substrate 14, if the size of the IC substrate 14 is larger and larger, the manufacturing yield of the machine can be speed up. However, it must take consideration on the maximum fabricating ability of the package machine. If the IC substrate 14 is too big, it must be sawing the IC substrate 14 first and then perform the following package steps of die boning and wire bonding. It prolongs the manufacturing time and could not cost down the manufacturing cost. Contrarily, it is more easily for the machine manufacturing if the size of the IC substrate 14 is smaller. However, the periphery area of the panel 10 could not effectively use, so the utility rate of the panel 10 is decrease a lot. Relatively, it would pay more cost of the panel material.

Obviously, according to the prior disadvantages of the size of the IC substrate and the manufacturing ability of the machine mentioned above, the main spirit of the present invention is to obtain an effective balance so as the present invention can simultaneously give consideration to the arrangement utility rate of the IC substrate and the panel and the problem of the manufacturing yield.

### SUMMARY OF THE INVENTION

The primary object of the present invention is to provide an arrangement structure applying to sawing a package panel, wherein the present invention can provide the optimum size of the IC substrate. According to the IC substrate size, the panel can be design with the best arrangement and the chip die arrangement of the IC substrate. On the purpose of not increasing the panel area, the present invention can obtain maximum amounts of chip dies to effectively improve the area utility rate of the panel and to substantially cost down the cost of the panel material.

Another object of the present invention is to provide an arrangement structure applying to sawing a package panel. In the present invention, the whole IC substrate can be firstly performed the die bond step and the wire bond step and then performed the sawing step so as to achieve the purpose of lowing down the utility rate of the machine and cost down the manufacturing cost.

A further object of the present invention is to provide an arrangement structure applying to sawing a package panel to enhance the manufacturing speed of the package and shorten the manufacturing time so as to achieve the purpose of effectively improving the yield.

In order to achieve previous objects, an arrangement structure applying to sawing a package panel includes at least rectangle panel, wherein a length of the panel is 16 inch and a width of the panel is 13.3 inch; and eight pieces rectangle integrated circuit (IC) substrates, wherein those IC substrates are arranged on the rectangle panel, and wherein a short side of each of those IC substrates is about 67 mm to 78 mm and a long side of each of those IC substrates is about 172 mm to 192 mm. Besides, as the length of the panel is 20 inch and the width of the panel is 16 inch, there are twelve or fourteen pieces rectangle integrated circuit (IC) substrates arranged on the panel.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a schematic representation of an arrangement structure applying to sawing a package panel, in accordance with the prior technology;

FIG. 2 is a schematic representation of an arrangement structure applying to sawing a package panel, in accordance with the present invention; and

FIG. 3a and FIG. 3b are schematic representations of two arranging structures applying for another panel size, in accordance with one embodiment of the present invention.

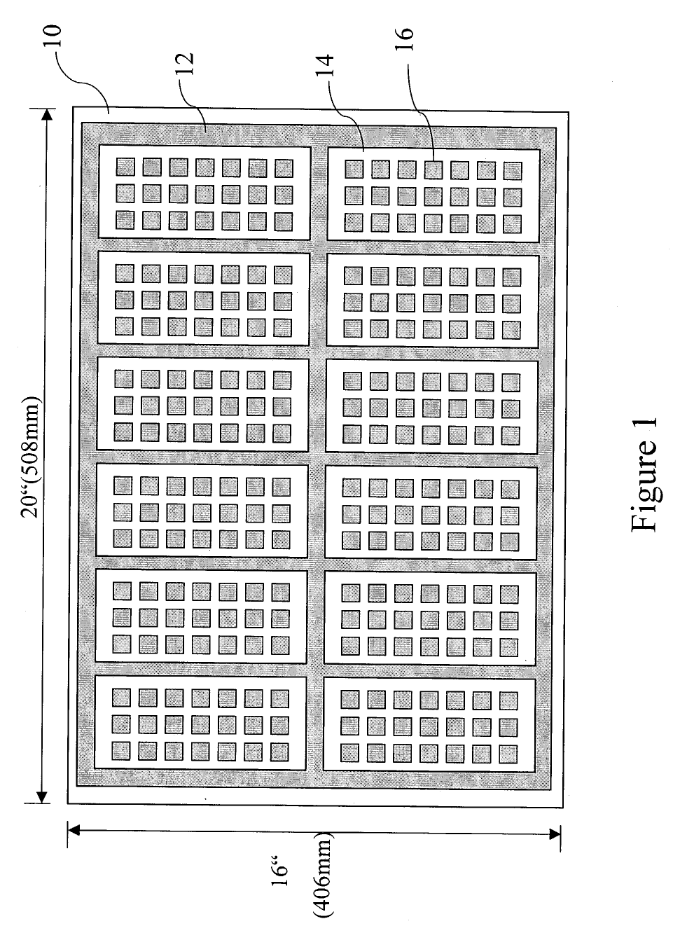

### DESCRIPTION OF THE PREFERRED EMBODIMENT

There are commonly two fixed sizes of the panel for the substrate material of packaging. According to panel for these two sizes, the present invention provides the optimum size and the arrangement design of the integrated circuit (IC) substrate so as the panel and the IC substrates can obtain maximum chip dies after sawing package and achieve the purpose of the maximum area utility rate of the panel.

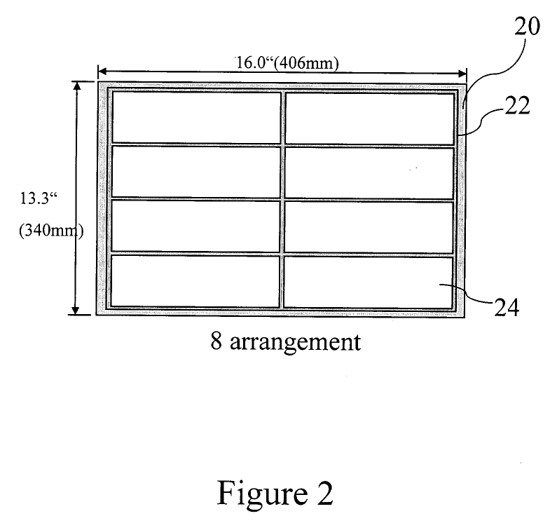

Referring to the FIG. 2, it is a schematic representation of an arrangement structure applying to sawing a package panel in accordance with the present invention. The arrangement structure includes a rectangle panel 20 with a length of 16 inch (406 mm) and a width of 13.3 inch (340 mm). There are eight pieces of the rectangle IC substrate 24 arranged within the effective using region 22 of the panel 20 and each of the IC substrate 24 has a short side about 67 mm to 78 mm and a long side about 172 mm to 192 mm.

The arrangement of these eight pieces of the IC substrate 24 is to arrange two rows of IC substrates 24 oriented to the length direction of the panel 20 and four rows of IC substrate 24 oriented to the width direction of the panel 20 so as to form a array of two multiplied by four, wherein the long side of those IC substrates 24 is parallel to the length direction of the panel 20.

Wherein, the size of the substrate 24 mentioned above is obtained by calculating in according to the size and its tolerance of the panel 20 and the maximum assembling ability of the package machine. Hence, the size of the IC substrate 24 is a numerical range. Besides, the present invention according to the size of the IC substrate 24 further designs the arrangement structure of the 8 arrangement.

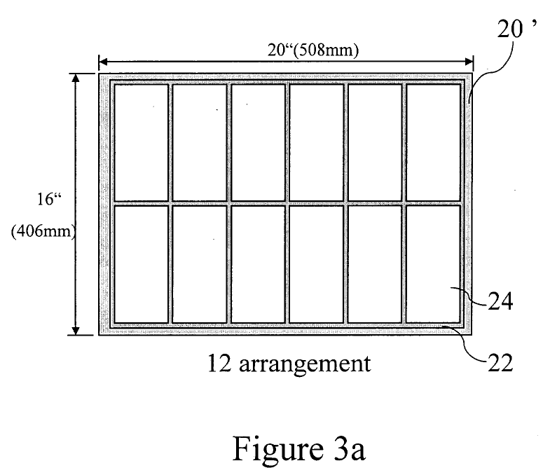

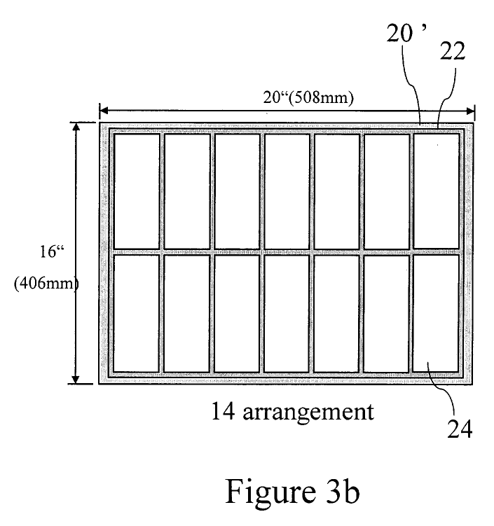

Referring to the FIG. 3, it is a schematic representation of an arrangement structure applying to the panel of another size in accordance with the present invention. The arrangement structure includes a rectangle panel 20′ with a length of 20 inch (508 mm) and a width of 16 inch (406 mm). There are twelve or fourteen pieces of the rectangle IC substrate 24 arranged within the effective using region 22 of the panel 20′ and each of the IC substrate 24 has a short side about 67 mm to 78 mm and a long side about 172 mm to 192 mm, which is as the same as the size range of the IC substrate 24 in the FIG. 2.

Such as shown in the FIG. 3a, the arrangement of these twelve pieces of the IC substrate 24 is to arrange as six rows of IC substrates 24 oriented to the length direction of the panel 20′ and two rows of IC substrate 24 oriented to the width direction of the panel 20′ so as to form a array of six multiplied by two, wherein the short side of those IC substrates 24 is parallel to the length direction of the panel 20′. Further referring to the FIG. 3b, the arrangement of these fourteen pieces of the IC substrate 24 is to arrange as seven rows of IC substrates 24 oriented to the length direction of the panel 20′ and two rows of IC substrate 24 oriented to the width direction of the panel 20′ so as to form a array of seven multiplied by two, wherein the short side of those IC substrates 24 is parallel to the length direction of the panel 20′. Wherein, in the example of the FIG. 3a and the FIG. 3b mentioned above, the size of the IC substrate 24 is 72 mm×185 mm and 68 mm×185 mm respectively.

After illustrating the arrangement structure of the IC substrate on the panel of the present invention, following, in order to understand the utility rate of the present invention apply for package sawing, herein is continuously illustrating the arrangement structure of the single packaged chip die on each IC substrate. To take the complementary metal oxide semiconductor (CMOS) chip die for an example, on the current CMOS chip die, there are mainly six sizes after packaged as shown in the following.

14.224 mm×14.224 mm;

11.43 mm×11.43 mm;

10.668 mm×10.668 mm;

9.02 mm×9.02 mm;

8.80 mm×8.80 mm; and

7 mm×7 mm°

(1). The amount of the CMOS chip dies arranged on the short side direction (67 mm˜78 mm) of the IC substrate 24 is as the following.

| | | |
|---|---|---|
| −14.224 | mm | 4 |
| −11.43 | mm | 5 |
| −10.668 | mm | 5˜6 |
| −9.02 | mm | 6˜7 |
| −8.80 | mm | 6˜7 |
| −7 | mm | 7˜9 |

(2). The amount of the CMOS chip dies arranged on the long side direction (172 mm˜192 mm) of the IC substrate 24 is as the following.

| | | |
|---|---|---|
| −14.224 | mm | 11˜12 |
| −11.43 | mm | 13˜15 |
| −10.668 | mm | 14˜16 |
| −9.02 | mm | 17˜18 |
| −8.80 | mm | 17˜19 |
| −7 | mm | 21˜23 |

(3). The amount of the different size CMOS chip dies arranged on the IC substrate 24, which has the size of (67 mm˜78 mm)×(172 mm˜192 mm), is as the following.

| | |
|---|---|
| −14.224 mm × 14.224 mm | 44˜48 |
| −11.43 mm × 11.43 mm | 65˜75 |
| −10.668 mm × 10.668 mm | 70˜96 |
| −9.02 mm × 9.02 mm | 102˜106 |
| −8.80 mm × 8.80 mm | 102-133 |
| −7 mm × 7 mm | 147-207 |

To take the CMOS chip die with the size 14.224 mm×14.224 mm for an example, owing to the short side of the IC substrate 24 is 67 mm˜78 mm and the long side is 172 mm˜192 mm, so there can arrange four chip dies on the short side of the IC substrate 24 and eleven to twelve chip dies on the long side of the IC substrate 24. Hence, there can arrange about forty-four to forty-eight chip dies on one IC substrate. And so on, other five sizes of CMOS chip dies can also have its maximum chip dies arranged on the IC substrate 24.

Hence, the present invention can obtain an effective balance between the substrate size and the manufacturing ability of the machine and simultaneously give consideration to the utility rate of the panel arrangement and the yield of manufacturing so as the present invention can obtain most amounts of chip dies to effectively improve the utility rate of the panel area and to substantially cost down the cost of the panel material on the purpose of not increasing the panel area.

Besides, owing to the limitation of the worse arrangement structure and the machine ability in the current package processes, it must be sawing the IC substrate 14 first and then perform the following package steps of die boning and wire bonding. It prolongs the manufacturing time and could not cost down the manufacturing cost. The present invention accords the panel size and the processing ability of the machine to calculate and integrate the optimum size of the IC substrate and then to design the arrangement structure depending on the size of the IC substrate. So in the manufacturing process of the present invention, the whole IC substrate can be firstly performed the die bond step and the wire bond step and then performed the sawing step so as to achieve the purpose of lowing down the utility rate of the machine and cost down the cost of manufacturing. Simultaneously, the present invention can also enhance the manufacturing speed of the package and shorten the manufacturing time so as to achieve the purpose of effectively improving the yield.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. An arrangement structure applying to sawing a package panel, said arrangement structure including:
at least a rectangle panel, wherein a length of said panel is 16 inch and a width of said panel is 13.3 inch; and
eight pieces rectangle integrated circuit (IC) substrates, wherein said pieces IC substrates are arranged on said rectangle panel, and wherein a short side of each of said IC substrates is about 67 mm to 78 mm and a long side of each of said IC substrates is about 172 mm to 192 mm.

2. The arrangement structure applying to sawing the package panel according to claim 1, wherein the arrangement of said eight pieces IC substrates is arranged two rows said IC substrates oriented to a length direction of said panel and four rows oriented to a width direction of said panel so as to form a array of two multiplied by four, and wherein said long side of said IC substrates is parallel with said length direction of said panel.

3. An arrangement structure applying to sawing a package panel, said arrangement structure including:
at least a rectangle panel, wherein a length of said panel is 20 inch and a width of said panel is 16 inch; and
twelve or fourteen pieces rectangle integrated circuit (IC) substrates, wherein said pieces IC substrates are arranged on said rectangle panel, and wherein a short side of each of said IC substrates is about 67 mm to 78 mm and a long side of each of said IC substrates is about 172 mm to 192 mm.

4. The arrangement structure applying to sawing the package panel according to claim 3, wherein the arrangement of said twelve pieces IC substrates is arranged six rows said IC substrates oriented to the length direction of said panel and two rows oriented to the width direction of said panel so as to form a array of six multiplied by two, and wherein said short side of said IC substrates is parallel with said length direction of said panel.

5. The arrangement structure applying to sawing the package panel according to claim 3, wherein the arrangement of said fourteen pieces IC substrates is arranged seven rows said IC substrates oriented to a length direction of said panel and two rows oriented to the width direction of said panel so as to form a array of seven multiplied by two, and wherein said short side of said IC substrates is parallel with said length direction of said panel.
